(19) United States
(12) Patent Application Publication
(10) Pub. No.: US 2025/0237693 A1
(43) Pub. Date: Jul. 24, 2025

(54) METHOD FOR MONITORING A STATE OF A CONTROL DEVICE

(71) Applicant: Robert Bosch GmbH, Stuttgart (DE)

(72) Inventors: Marcel Rudolph, Renningen (DE); Benjamin Nikolas Fischle, Murr (DE)

(21) Appl. No.: 19/032,832

(22) Filed: Jan. 21, 2025

(30) Foreign Application Priority Data
Jan. 22, 2024 (DE) 10 2024 200 542.8

(51) Int. Cl. G01R 31/28

(52) U.S. Cl. CPC G01R 31/2837

(57) ABSTRACT

A method for monitoring the state of a control device. In the method, a curve of a supply voltage of the control device when switching the control device is evaluated using a first monitoring module, wherein a current response time is determined, which is compared with an initial value for the response time so that a difference value, which carries information on the state of the control device, is ascertained.

### FIELD

The present invention relates to a method for monitoring a state of a control device and to an arrangement for performing the method.

### BACKGROUND INFORMATION

Control devices are electronic modules that are used in places where something needs to be controlled or regulated. In motor vehicles, control devices are used in different areas.

Monitoring the state, in particular the technical state, in modern control devices, for example sensor control devices, in particular in systems with high SAE (Society of Automotive Engineers) ASIL (Automotive Safety Integrity Level) ratings, i.e., level 2 or higher, is becoming increasingly more important. In particular for L4 control devices used in vehicles, such as commercial vehicles, it is important to know when the control device needs to be serviced or replaced.

In order to achieve this goal, new approaches must be used to check the technical state of the control device. Due to the very high costs of each control device, a simple approach using a timer or counter is not sufficient.

In L3+ systems, all supply voltages or rails are monitored with a monitoring unit that can measure the present voltage of the rail by means of an analog-to-digital converter (ADC) and compare it with a calculated minimum or maximum threshold value of the rail, usually within a window of +/−3%. Furthermore, continuous monitoring can be carried out with a comparator against other threshold values. Usually, maximum ratings of a powered device, such as an SoC (system on chip), are used. The ADC can detect slow voltage fluctuations and check whether the voltage is within a specified range, which is called low-frequency monitoring. The comparator can detect rapid voltage spikes and drops, which is called radio-frequency monitoring. For both methods, the monitoring threshold values are given individually for both overvoltages and undervoltages.

The monitoring unit also has the ability to measure the switch-on time and switch-off time for the assigned rail in order to check whether the switch-on sequence and the switch-off sequence are as defined by said unit. In this context, reference is made to FIG. 1, which shows the basic schematic.

German Patent Application No. DE 10 2019 213 654 A1 describes a method for checking the functionality of an autonomous supply unit of a control device for at least one personal protection device in a vehicle. In the method, the detection of a voltage is decoupled, a duration is detected, and the functionality of the autonomous supply unit is detected depending on the detected voltage and/or the detected duration.

A method for operating a controller for a starting device is described in Germany Patent Application No. DE 10 2009 047 034 A1. The starting device has a starter motor for starting an internal combustion engine of a vehicle with an on-board electrical system. The starter motor is controlled by the controller, in particular for a start-stop operating mode of the vehicle. In order to reduce a load on the on-board electrical system, in particular a voltage drop, during the starting process, the controller detects at least one parameter for determining a state of the on-board electrical system, wherein the starter motor is controlled at least depending on the parameter.

### SUMMARY

A method and an arrangement are provided according to the present invention. Example embodiments of the present invention can be found in the disclosure herein.

The presented method is used to monitor the state of a control device. In the method, a curve of a supply voltage of the control device when switching, in particular when switching on, the control device is evaluated by means of a first monitoring module, wherein a current response time or response duration is determined, which is compared with an initial value for the response time so that a difference value, which carries information on the state of the control device, is ascertained.

In one example embodiment of the present invention, in which a start-up of the control device is examined, a start-up time or start-up duration is used as the response time. In another embodiment, in which a power-off or switching-off of the control device is examined, a decay time or decay duration is examined.

According to an example embodiment of the present invention, a method which is used in embodiments to monitor the state of the energy supply and some PCB parameters (PCB: printed circuit board) is presented.

The presented arrangement or monitoring arrangement of the present invention is used to perform the method of the present invention described and is implemented, for example, in hardware and/or software. The arrangement can be integrated in a control device of a motor vehicle or designed as such.

Further advantages and embodiments of the present invention can be found in the description and the figures.

Of course, the features mentioned above and those still to be explained below can be used not only in the respectively specified combinations but also in other combinations or alone, without departing from the scope of the present invention.

### BRIEF DESCRIPTION OF THE DRAWINGS

FIG. 1 shows a block diagram of an example embodiment of the presented monitoring arrangement of the present invention

FIG. 2 shows a graph of voltage curves for illustrating the method of the present invention presented.

FIG. 3 shows a graph of voltage curves for illustrating an example embodiment of the method of the present invention.

FIG. 4 shows a block diagram of an example embodiment of the presented monitoring arrangement of the present invention.

FIG. 5 shows a graph of further voltage curves.

FIG. 6 is a schematic, highly simplified representation of a vehicle with a control device according to an example embodiment of the present invention.

### DETAILED DESCRIPTION OF EXAMPLE EMBODIMENTS

The present invention is shown schematically in the figures on the basis of embodiments and is described in detail below with reference to the figures.

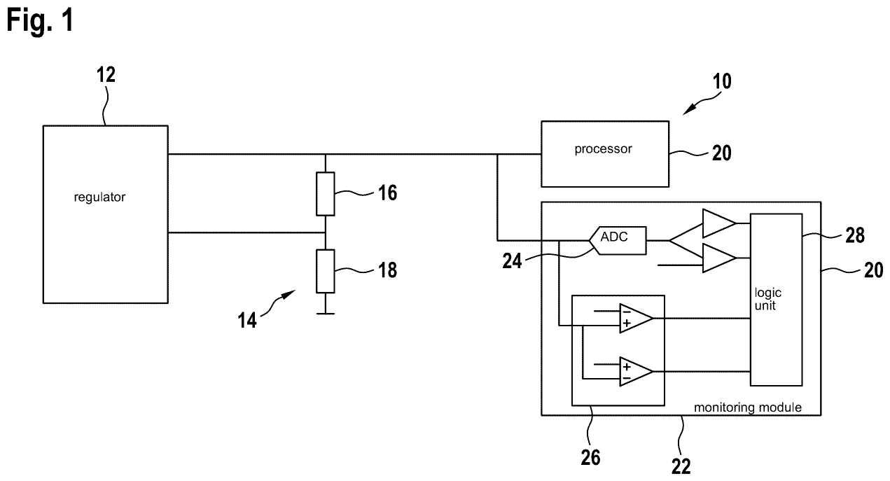

FIG. 1 shows a basic circuit diagram of an arrangement for monitoring or a monitoring arrangement, which is denoted overall by reference sign 10. The representation shows a regulator 12, a voltage divider 14 with resistors R1 16 and R2 18, a processor 20 as a consumer, which in this case is designed as an SoC. The representation also shows a monitoring module 22, in which an ADC (analog-to-digital converter) 24, which operates slowly, and a comparator 26, which operates continuously, and a logic unit 28 are provided.

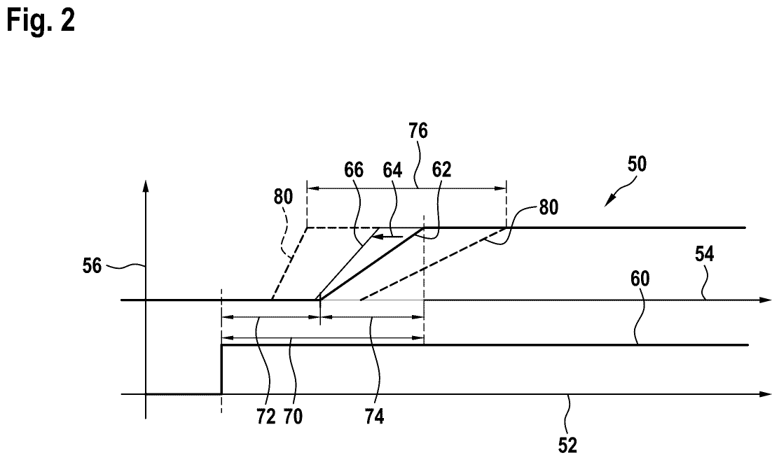

FIG. 2 shows a graph 50 of voltage curves, with the time plotted on the abscissas 52 and 54 and the voltage plotted on the ordinate 56. The representation shows an input signal curve 60, which shows a switch-on pulse, and an examined signal curve 62, which shifts, as illustrated by arrow 64, toward a curve 66.

Double arrow 70 denotes a typical time in which the voltage has reached the setpoint after switching on. This time is ascertained individually for each device in the new state, is stored and, each time the device is started, is measured and compared with the initial value ascertained in the new state. Double arrow 72 illustrates a switch-on delay of the voltage regulator, namely, the time that elapses while the regulator waits after the switch-on signal before it starts regulating. Double arrow 74 illustrates the time the regulator needs until the voltage is stable, which is also called soft start time. Reference sign 76 illustrates the curve of the regulator output voltage.

In modern control devices, the correct switch-on sequence and switch-off sequence are checked by means of on-board monitoring units, as shown in FIG. 2. The minimum and maximum running time or operating time for each rail is therefore calculated relative to the enable signal or activation signal of the first rail, as illustrated in FIG. 2 by the dotted lines 80. Measurements are then taken each time the main SoC is started up or put into operation, and it is checked whether the sequence is being followed. The tolerance is caused by the input parameters:

Soft start of the regulator (regulator+ext. RC),
EN (enable) delay in the regulator,
EN delay in the switch-on sequence.

A first aspect of the presented method is examined in more detail here:

In a new control device, the signal curve 62 shown in FIG. 2 shows the rising ramp (ramp-up) of the voltage. The time measured during the first start-up, e.g., measured in the controlled system at the end of the line test, should be stored in a non-volatile memory (NVM). In practice, this time is measured every time the SoC starts up. Due to the aging of the components, the signal curve 62 will shift to the left or right, for example to the curve 66 in FIG. 2.

By comparing the start-up time with the initial value, the time difference can be calculated. This degradation can be used to estimate the end of operation of the regulator and of the external circuit. After shifting by a certain percentage, the end of operation of the control device can be estimated well.

It should be noted that, during the start-up sequence, the regulator and its external circuit are of particular interest.

The power-off process is discussed below.

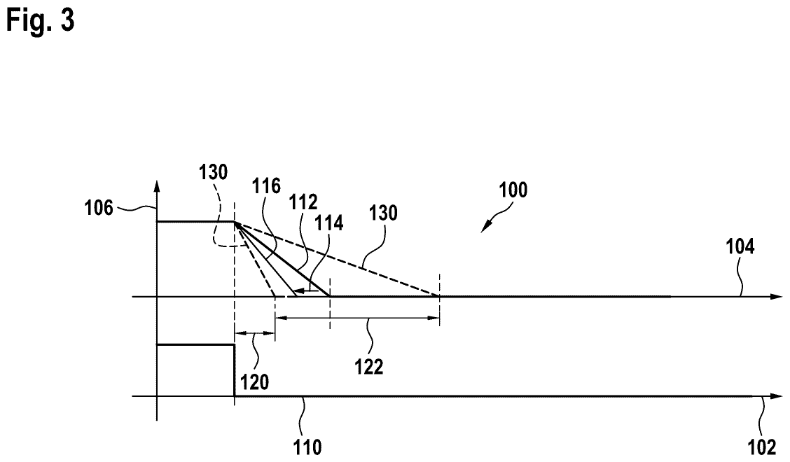

FIG. 3 shows a graph 100 of voltage curves, with the time plotted on the abscissas 102 and 104 and the voltage plotted on the ordinate 106. The representation shows an input signal curve 110, which includes a switch-off pulse, and an examined signal curve 112, which shifts, as illustrated by arrow 114, toward a curve 116.

Double arrow 120 illustrates a discharge time from the power-off signal until the output voltage is below a defined threshold, e.g., 0.2 V. Double arrow 120 shows the variance of the time 120, which is given by component tolerances.

The correct switch-off sequence is of great importance for modern SoCs. This is also checked by such external monitoring. The decay time or power-off time for each rail is calculated with all tolerances, dotted lines in FIG. 3. The input parameters are:

capacitance of the buffer capacitors,
discharge current,
voltage on every rail,
discharge current for each rail,
deactivation delay/order in the energy sequence.

During power-off, each rail usually has an active discharge in order to ensure a rapid and defined discharge of each rail. Usually, the activation signal of the regulator inverts the discharge signal for the assigned rail.

A further aspect of the presented method is discussed below.

In a new control device, the signal curve 112 shown in FIG. 3 shows the falling ramp of the voltage. The time measured during the first power-off, e.g., measured in the controlled system at the end of the line test, should be stored in a non-volatile memory. In practice, this time is measured each time the SoC is powered off. Due to the aging of the components, the signal curve 112 will shift to the left, e.g., to the curve 116 in FIG. 3.

By comparing the decay time with the initial value, the time difference can be calculated. This degradation can be used to estimate the end of life of the decoupling capacitors and the external circuit. After shifting by a certain percentage, the end of operation of the control device can be estimated well.

During the switch-off sequence, the capacitors and the discharge circuit are of particular interest.

The dynamic check of the decoupling and of the regulators is discussed here:

The tests described above check the static behavior of the external circuit. This already gives a good indication but is not sufficient for high-power core rails. Due to the very high peak currents, in the range of 100 to 200 A, and the very high power integrity requirements of these rails, additional monitoring is necessary. One goal of this monitoring is to check the power integrity of the core rails. Influence on the integrity is given by the following parameters:

capacitance of the decoupling capacitors,
internal resistance of the capacitors,
PCB core material (permittivity, later called epsilon 0).

A further aspect of the presented method is discussed here:

In order to examine the rails, taking into account degradation and aging, further monitoring is required for all high-power rails, e.g., for core rails, DDR rails (DDR corresponds to RAM), and high-power rails in general.

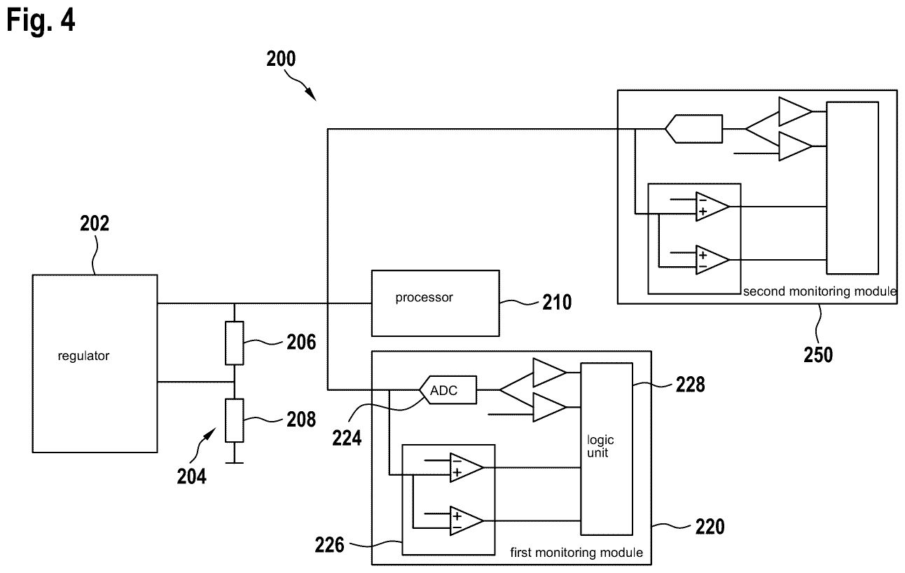

FIG. 4 shows a circuit diagram of a further monitoring arrangement, which is denoted overall by reference sign 200. The representation shows a regulator 202, a voltage divider 204 with resistors R1 206 and R2 208, and a processor 210 as a consumer, which in this case is designed as an SoC. The representation furthermore shows a first monitoring module 220, in which an ADC 224, which operates slowly, and a comparator 226, which operates rapidly, and a logic unit 228 are provided. Furthermore, a correspondingly constructed second monitoring module 250 is provided.

The existing monitoring by the first monitoring module 220 cannot be used for this task because this first monitoring module 220 must ensure that the supply voltage is always within the maximum classification or assessment.

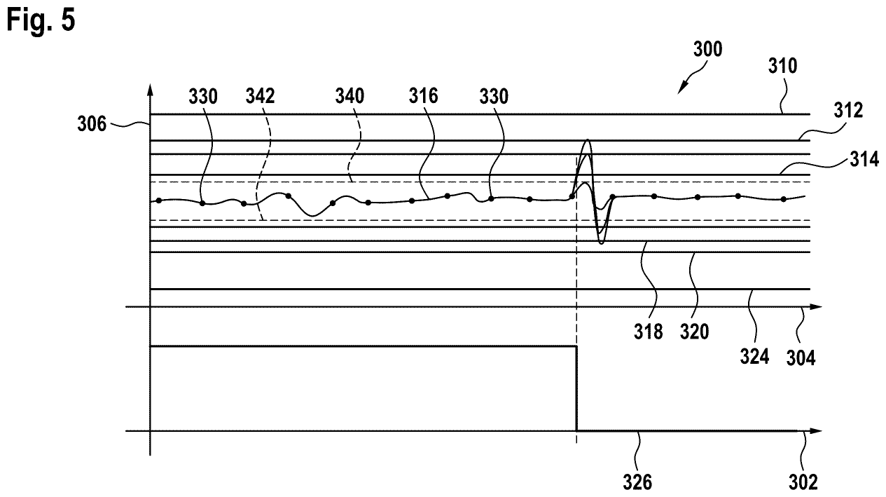

Both monitoring modules 220 and 250 are identical, i.e., the hardware is the same, but the configuration of the threshold values is different. Each monitoring has the option to measure the average voltage by means of an ADC and to trigger a response if the given threshold values are reached. Measuring by means of an ADC is always discrete in time and not continuous, which in turn means that small peaks may be lost. This is shown in FIG. 5.

FIG. 5 shows a graph 300 of various curves, namely, the maximum range 310, with the time plotted on the abscissas 302 and 304 and the voltage plotted on the ordinate 306. Reference sign 312 indicates that, after a certain amount of aging of the device, the initial threshold 314 is exceeded in order to determine by how much this threshold is increased until it is not exceeded even under high load. Reference sign 312 indicates an initial threshold for voltage monitoring, deliberately below the maximum permissible threshold, which will not be exceeded in a new device. Reference sign 316 indicates an example of a discrete voltage curve. Reference sign 318 is analogous to 314, only downward. Reference sign 320 is analogous to 312, only downward. Reference sign 324 denotes a permissible voltage. A curve 326 indicates an error signal.

Points 330 are ADC sample points. The threshold values in the second monitoring module for the ADC are identical to those configured in the second monitoring module, namely, dotted lines 340 and 342.

The difference is in the high-frequency monitoring with the comparators. The threshold value is decreased close to or to the 3% line; in FIGS. 5, 310 and 324 is the threshold value used for the first monitoring module, and 314 and 318 is the threshold value used for the second monitoring module.

In a new control device, 314 and 318 will not be reached due to the good state of all components. Due to the aging of the decoupling capacitors, the voltage drops or voltage spikes will increase and reach the threshold value (reference signs 314 and 318). This does not pose a problem for the overall operation of the SoC.

The change in the threshold should be made gradually until the threshold value is not reached for a long operating time, e.g., one hour. After a few more hours of operation, due to aging of the components, such as capacitors, this threshold value is also reached and it must be adjusted, e.g., to the threshold value (reference signs 312 and 320). It is important that each change must be within the range of the maximum values, threshold value (reference signs 310 and 324).

With the information on the change between the threshold value (reference signs 314 and 318) and the threshold value (reference signs 312 and 320), i.e., operating time and voltage change, the remaining operating time until the maximum classification is reached can be calculated.

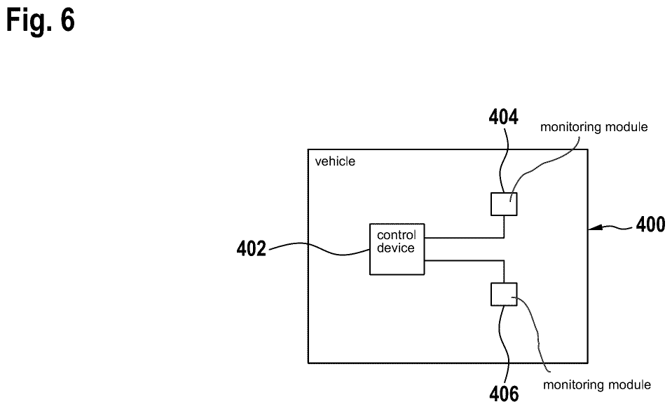

FIG. 6 is a highly simplified representation of a vehicle 400 with a control device 402, whose status is monitored. A first monitoring module 404 and a second monitoring module 406 are used for this purpose. The two monitoring modules 404, 406 are typically arranged in an arrangement for monitoring or a monitoring arrangement.

1-9. (canceled)

10. A method for monitoring a state of a control device, the method comprising the following steps:
evaluating, using a first monitoring module, a curve of a supply voltage of the control device when switching the control device, and determining a current response time;
comparing the current response time with an initial value for the response time so that a difference value, which carries information on the state of the control device is ascertained.

11. The method according to claim 10, wherein the method is performed when starting up the control device, wherein a current start-up time as the current response time is compared with an initial start-up time as the initial response time.

12. The method according to claim 10, wherein the method is performed when powering off the control device, wherein a current decay time as the current response time is compared with an initial decay time as the initial response time.

13. The method according to claim 10, in which a second monitoring module is used.

14. The method according to claim 10, wherein in which a value for the initial response time is used, the value having been stored in a non-volatile memory.

15. An arrangement for monitoring a state of a control device, the arrangement comprising a first monitoring module, and the arrangement being configured to:
evaluate, using the first monitoring module, a curve of a supply voltage of the control device when switching the control device, and determining a current response time;
comparing the current response time with an initial value for the response time so that a difference value, which carries information on the state of the control device is ascertained.

16. The arrangement according to claim 15, further comprising a second monitoring module.

17. The arrangement according to claim 15, wherein the first monitoring module includes an analog-to-digital converter configured to check slow voltage changes, and a comparator configured to check rapid voltage changes.

18. The arrangement according to according to claim 16, wherein the second monitoring module includes an analog-to-digital converter configured to check slow voltage changes, and a comparator configured to check rapid voltage changes.
